(19) United States
(12) Patent Application Publication
(10) Pub. No.: US 2005/0009239 A1
(43) Pub. Date: Jan. 13, 2005

(54) Optoelectronic packaging with embedded window

(76) Inventors: Larry Lee Wolff, Pak Kret (TH); Wichai Yansalee, Thanyaburi (TH)

Correspondence Address: BRUCE E. WEIR, 12 SPARROW VALLEY COURT, MONTGOMERY VILLAGE, MD, 20886-1265, US

(21) Appl. No.: 10/613,089

(22) Filed: Jul. 7, 2003

(51) Int. Cl. H01L 21/44

(52) U.S. Cl. 438/123

(57) ABSTRACT

A method for encapsulating optoelectronic components. An optical semiconductor die is attached to a lead frame or a substrate. A solid window transparent to light and no larger than the die area, excluding wire bond pads, is cut, scored, or otherwise singulated from glass or plastic. A transparent adhesive is applied to the optically-sensitive portion of the die, then the window is placed on the optically-sensitive portion of the die by a pick-and-place machine, forming a transparent aperture. Wires connect die circuitry to electrical leads on the lead frame or substrate. The assembly is encapsulated in molding material, leaving the upper surface of the window and the electrical leads exposed.

### FIELD OF THE INVENTION

The present invention relates to the packaging of optical semiconductor or optoelectronic devices.

### BACKGROUND OF THE INVENTION

Optical semiconductors are key components in a wide variety of electronic devices. Because optical semiconductors are fragile and subject to damage by impact, abrasion, contaminants, moisture, heat, and other factors, each optical semiconductor is typically encased in a protective package. However, unlike the protective packages used to encase most other electronic components, the package for an optical semiconductor must incorporate a region that is transparent to light.

It has been a common practice to create an optoelectronic sensor package by mounting a sensor within a ceramic container with embedded conductive leads, then sealing the container with a window made of optical glass. The window does not directly contact the sensor, instead leaving some air space between the window and the sensor.

While this method can produce a relatively rugged sensor package with good optical properties, the enclosed space between the window and the die may contain moisture that can condense within the package. The enclosed space also adds at least two boundary layers to the light path, possibly resulting in unwanted reflection, refraction, or dispersion of light. These undesirable effects may be intensified if the plate is not parallel to the die surface.

Therefore, the requirements for extremely clean manufacturing conditions, humidity control within the container, and precise sensor die positioning with respect to the window often result in a packaged sensor that is bulky and expensive, sometimes accounting for half the total cost of a finished product.

Recent improvements in adhesives and manufacturing technology have made possible the simultaneous fabrication of large numbers of identical sensor packages in which the window is bonded directly to the die, thereby eliminating enclosed air space. This is accomplished by bonding a single sheet of suitable window material to an array of optical semiconductors, then cutting the sheet to separate the individual packages. Low-cost plastic encapsulation material may be used to seal the portions of the die that remain exposed.

While this method mitigates many of the problems arising from inclusion of an air space between a window and a die, the resulting package may retain a considerable amount of unusable window material, which, being heavy and expensive relatively to plastic encapsulation materials typically used to complete the package, adds unwanted weight and cost to the finished product. Further, every window produced in a given production run is essentially the same, limiting the manufacturer's ability to adapt to market demands by economically producing small numbers of sensor packages with windows having different characteristics.

What is needed, then, is a method for manufacturing a packaged optoelectronic sensor that reduces the bulk and cost of the packaged sensor while providing adequate protection for the die and mitigating the problems arising from space between the window and die. Windows should be placed and bonded individually, allowing flexibility in the manufacturing process. The method should utilize standard manufacturing equipment and raw materials.

### SUMMARY OF THE INVENTION

The present invention is a manufacturing method that utilizes standard manufacturing equipment and raw materials to produce compact, low-cost packaged optoelectronic components such as Erasable Programmable Read Only Memory (EPROM) chips, Electrically Erasable Programmable Read Only Memory (EEPROM) chips, Charge-Coupled Device (CCD) chips, Complementary Metal Oxide Semiconductor (CMOS) chips, and other optical semiconductor devices that are known in the art.

In a preferred embodiment of the present invention an aperture member is created from optical glass, plastic, or other materials that are transparent to the radiation spectra of interest. The material may be selected to absorb or pass specific radiation frequencies. An aperture member is typically cut from a plate of suitable material by a sawing, dicing, or scribing process, although other known processes may be used. The aperture member may be shaped, scored, or otherwise modified to refract, diffract, or diffuse light passing through. The aperture member may be sized and shaped to cover any portion of a semiconductor die, but is preferably sized to cover only the optically-sensitive portion of the die. Since the aperture member is individually manufactured, it may be of any suitable thickness and may have a horizontal cross-section of any suitable shape.

A semiconductor die with an optically-sensitive portion is then mounted on a lead frame. A computer-controlled pick-and-place machine selects an aperture member with desired characteristics. Pick-and-place machines are standard semiconductor manufacturing devices and may be programmed to select and precisely place a different component from one operation to the next. A transparent adhesive is applied to the aperture member, or to the die, or to both, then the pick-and-place machine positions the aperture member over the optically-sensitive portion of the die. The aperture member is pressed against the die, allowing the transparent adhesive to bond the aperture member to the die. The transparent adhesive may be an epoxy, silicon, tape, or other adhesive materials that are known in the art.

Since the aperture member is attached directly to the die, no intervening air space remains to produce condensation or unwanted reflection, refraction, or diffusion. Since the aperture member is pre-sized and pre-shaped to cover the optically-sensitive portion of the die, the surfaces of the aperture member are automatically made parallel to the die surface upon installation and require no further cutting. Both the aperture member material and the transparent adhesive may be selected for desired refractive index, absorption, or other physical characteristics. The assembly is encapsulated with an epoxy molding compound or other encapsulate as is known in the art, leaving the leads and the upper portion of the aperture member exposed.

In an alternate embodiment of the present invention, a semiconductor die with an optically-sensitive area may be mounted with an adhesive material on a Printed Circuit Board (PCB) or ceramic substrate. The adhesive material may be a silver-filled epoxy, a polyimide epoxy, a thermally-conductive epoxy, a thermally or electrically non-conductive epoxy, an adhesive tape, or a metal alloy.

Metal wires such as gold, aluminum, or copper are bonded between the semiconductor die and the active circuitry on the substrate. A transparent adhesive is applied to the semiconductor die or to an aperture member made of borosilicate glass or another suitable material known in the art. The aperture member is placed on the optically-sensitive portion of the die by a pick-and-place machine. The assembly is baked. The die, aperture member, and substrate are encapsulated with an epoxy molding compound. Finally, the individual die package is separated from any attached frame or substrate and visually inspected.

### DESCRIPTION OF THE DRAWINGS

FIG. 1 shows a perspective view of an encapsulated optoelectronic device.

FIG. 2 shows a cutaway view of the encapsulated optoelectronic device of FIG. 1, revealing portions of a lead frame, semiconductor die, and embedded aperture member.

FIG. 3 is a cross-sectional view of the encapsulated optoelectronic device of FIG. 1.

FIGS. 4A through 4E are cross-sectional views showing the assembly of a Through Hole Device (THD) package.

FIGS. 5A through 5E are cross-sectional views showing the assembly of a Surface Mount Device (SMD) package.

FIGS. 6A through 6E are cross-sectional views showing the assembly of a Plastic Non-Leaded package.

FIGS. 7A through 7E are cross-sectional views showing the assembly of a package with a substrate, such as a Land Grid Array (LGA) or a Ball Grid Array (BGA) package.

### DETAILED DESCRIPTION OF THE INVENTION

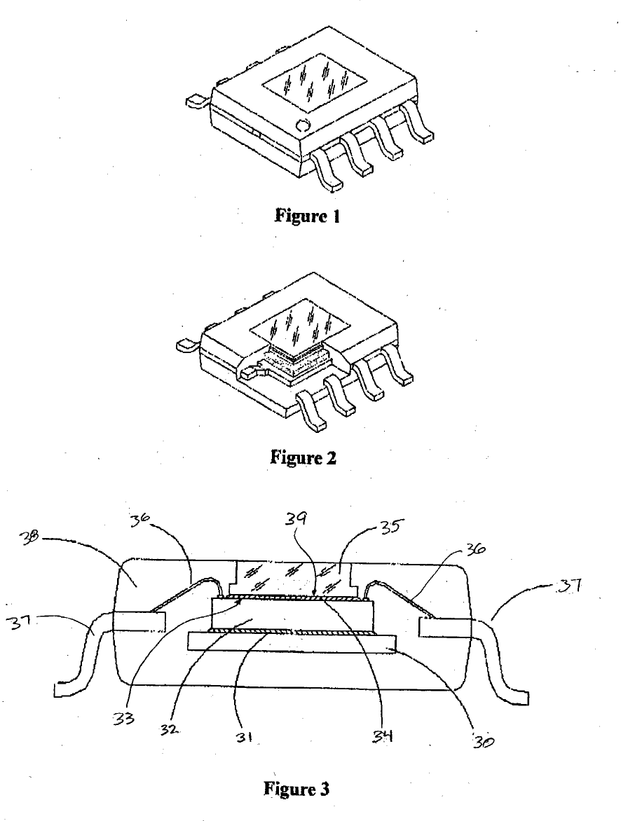

FIGS. 1, 2, and 3 show different views of an embodiment of the present invention. FIG. 1 shows a perspective view of an encapsulated optoelectronic device. FIG. 2 shows a cutaway view of the same device, revealing portions of a lead frame, semiconductor die, and embedded aperture member. FIG. 3 is a cross-sectional view of the same device. In FIG. 3, an optical semiconductor die 32 is secured upon a die paddle 30 with an adhesive epoxy material 31 or other bonding agent known in the art. Metal wires 36 are bonded from semiconductor die 32 to external metal leads 37, which connect the circuitry of the semiconductor die 32 to external circuitry (not shown).

A transparent adhesive 34 is then applied to the optically active upper surface 33 of the semiconductor die 32. An aperture member 35 made of borosilicate glass or other suitable material known in the art is placed by a pick-and-place machine on the upper surface of transparent adhesive 34, affixing the aperture member 35 to the transparent adhesive 34 and the optically active upper surface 33 of the semiconductor die 32, forming a transparent aperture above the optically active upper surface 33. The pick-and-place machine may according to its programming instructions select an aperture member with any desired characteristics. Since in accordance with the method of the present invention each aperture member is individually placed and affixed to a semiconductor die, the pick-and-place machine may select a different type of aperture member for each of any number of sequentially-assembled optoelectronic packages.

An aperture member may be created from optical glass, plastic, or other materials that are transparent to the radiation spectra of interest. The material may be selected to absorb or pass specific radiation frequencies. An aperture member is usually cut from a plate of suitable material by a sawing, dicing, or scribing process, although other known processes may be used. The aperture member may be shaped, scored, or otherwise modified to refract, diffract, or diffuse light passing through. The aperture member may be sized and shaped to cover any portion of a semiconductor die, but is preferably sized to cover only the optically-sensitive portion of the die. Since the aperture member is individually manufactured, it may be of any suitable thickness and may have a horizontal cross-section of any suitable shape.

No open space is left between the semiconductor die 32 and the aperture member 35 after the two parts are bonded. An epoxy molding compound or other encapsulate as is known in the art is formed around the die paddle 30, semiconductor die 32, and aperture member 35, leaving the upper surface of the aperture member 35 and the external metal leads 37 exposed.

In an alternate embodiment of the present invention, the transparent adhesive 34 may be applied to a lower surface 39 of the aperture member 35, with the lower surface 39 of the aperture member 35 then being positioned by a pick-and-place machine against the optically active upper surface 33 of the semiconductor die 32.

In still another embodiment of the present invention the order of assembly steps may be varied. A transparent adhesive 34 is applied to the optically active upper surface 33 of the semiconductor die 32. An aperture member 35 made of borosilicate glass or another suitable material as is known in the art is placed by a pick-and-place machine on the optically active upper surface 33 of the semiconductor die 32 and affixed to the transparent adhesive 34, forming a transparent aperture above the optically active upper surface 33. No open space is left between the semiconductor die 32 and the aperture member 35 after the two parts are bonded.

An optical semiconductor die 32 is then secured upon a die paddle 30 with an adhesive epoxy material 31 or other bonding agent known in the art. Metal wires 36 are bonded from semiconductor die 32 to external metal leads 37, which connect the circuitry of the semiconductor die 32 to external circuitry (not shown). An epoxy molding compound or other encapsulate as is known in the art is formed around the die paddle 30, semiconductor die 32, and aperture member 35, leaving the upper surface of the aperture member 35 and the external metal leads 37 exposed.

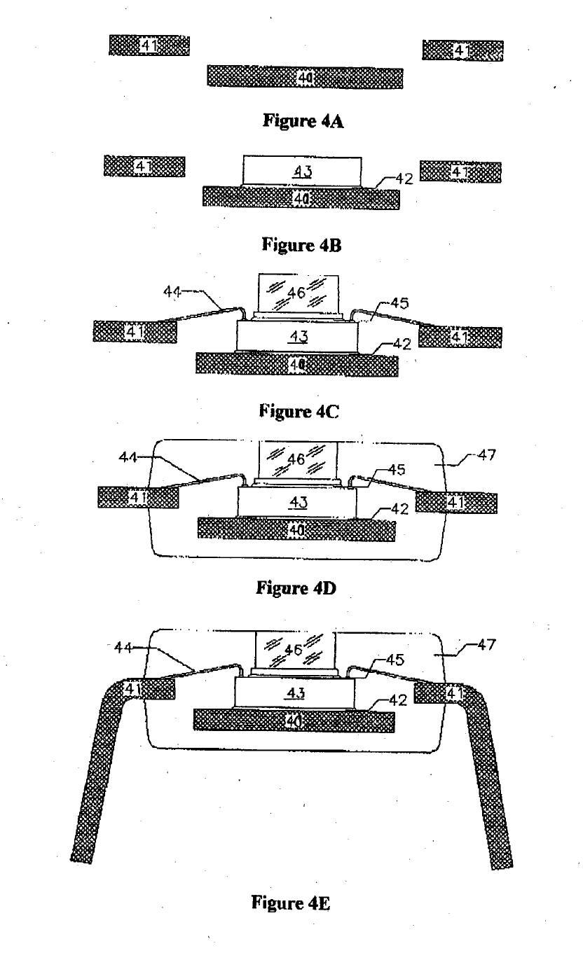

FIGS. 4A through 4E show the assembly of a preferred embodiment of the present invention. FIG. 4A shows a cross-sectional view of a metal lead frame as is known in the art, with a die paddle 40 and metal leads 41. The lead frame is configured to accommodate a desired semiconductor and related electrical circuitry.

FIG. 4B shows a semiconductor die 43 attached by an adhesive material 42 to the upper surface of the die paddle 40. The adhesive material 42 may be dispensed, stamped, laminated, or applied by other means known in the art atop the die paddle 40. The adhesive material 42 can be a silver-filled epoxy, a polyimide epoxy, a thermally-conductive epoxy, a thermally or electrically nonconductive epoxy, an adhesive tape, or a metal alloy. The adhesive material 42 is heated and cured, thereby securing the semiconductor die 43 to the die paddle 40.

In FIG. 4C, metal wires 44 are bonded between the semiconductor die circuitry (not shown) and the metal leads 41, connecting the die circuitry to external circuitry (not shown). The metal wires 44 may comprise gold, aluminum, copper or other suitable materials as are known in the art. An aperture member 46 is attached upon an optically-sensitive area of the die with a transparent adhesive material 45. The transparent adhesive material 45 may be dispensed, stamped, laminated, or applied by other means known in the art to either upper surface of the semiconductor die 43 or the lower surface of the aperture member 46.

FIG. 4D shows a cross-sectional view of the present invention after the die paddle 40, the semiconductor die 43, and aperture member 46 are encapsulated with an epoxy molding compound as is known in the art, forming a package 47 while leaving the upper surface of the aperture member 46 and the metal leads 41 exposed.

FIG. 4E shows the exposed metal leads 41 formed at approximately a 90-degree angle with respect to the plane of the die paddle 41, creating a device especially suited for application as a Through Hole Device (THD) such as a Plastic Dual-Inline Package (PDIP). Finally, the individual package is punched out or cut from any attached metal frame to become a finished package.

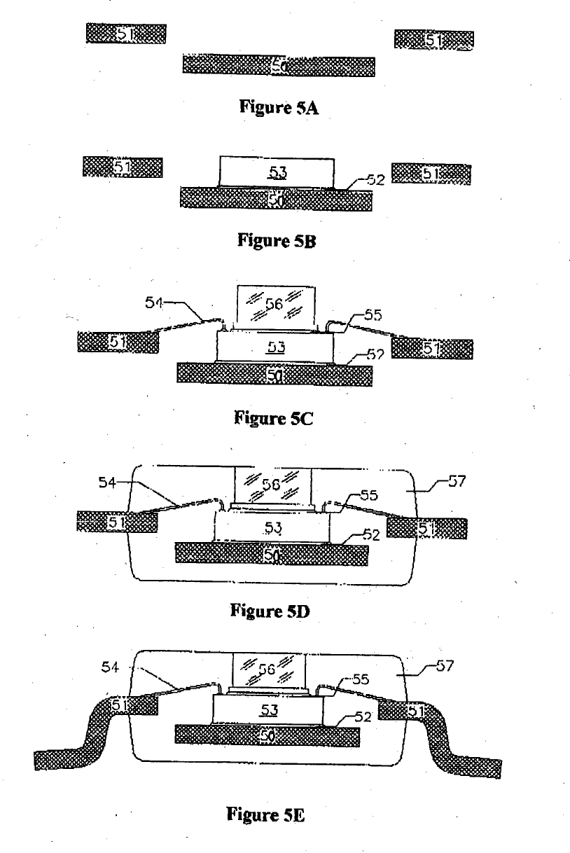

FIGS. 5A through 5E show the assembly of an embodiment similar to that shown in FIGS. 4A through 4E, except that in FIG. 5E the exposed parts of the metal leads 51 may be formed as a gull wing, a J-form, or a C-form as required by external circuitry, creating a device especially suited for use as a Surface Mount Device (SMD) package such as a Plastic Leaded Chip Carrier (PLCC), a Small Outline Plastic (SOP), a Small Outline Integrated Circuit (SOIC), or a Plastic Quad Flat Pack (PQFP).

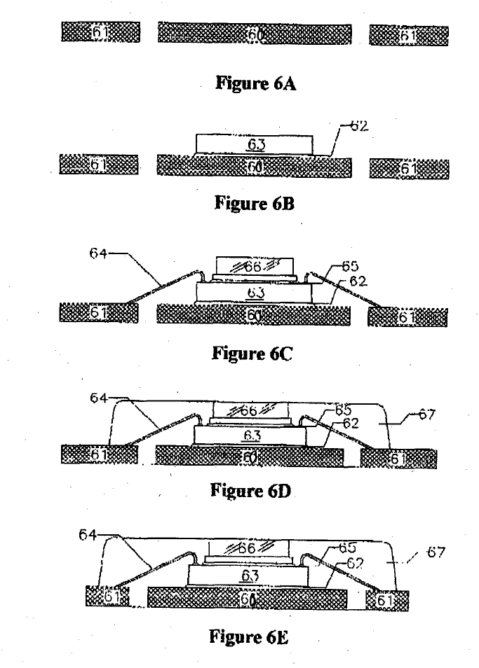

FIGS. 6A through 6E show the assembly of an embodiment especially suited to non-leaded surface mount applications such as a Plastic Non-Leaded package or a Quad Flat Pack Non-leaded (QFPN). FIG. 6A shows a cross-sectional view of a metal frame as is known in the art, with a die paddle 60 and metal contacts 61. The frame is configured to accommodate a desired semiconductor and related electrical circuitry.

FIG. 6B shows a semiconductor die 63 attached by an adhesive material 62 to the upper surface of the die paddle 60. The adhesive material 62 may be dispensed, stamped, laminated, or applied by other means known in the art atop the die paddle 60. The adhesive material 62 can be a silver-filled epoxy, a polyimide epoxy, a thermally-conductive epoxy, a thermally or electrically nonconductive epoxy, an adhesive tape, or a metal alloy. The adhesive material 62 is heated and cured, thereby securing the semiconductor die 63 to the die paddle 60.

In FIG. 6C, metal wires 64 are bonded between the semiconductor die circuitry (not shown) and the metal contacts 61, connecting the die circuitry to external circuitry (not shown). The metal wires 64 may comprise gold, aluminum, copper or other suitable materials as are known in the art. An aperture member 66 is attached upon an optically-sensitive area of the die with a transparent adhesive material 65. The transparent adhesive material 65 may be dispensed, stamped, laminated, or applied by other means known in the art to either upper surface of the semiconductor die 63 or the lower surface of the aperture member 66.

FIG. 6D shows a cross-sectional view of the present invention after the semiconductor die 63, the aperture member 66, and the upper portions of the die paddle 60 are encapsulated with an epoxy molding compound as is known in the art, forming a package 67 while leaving the upper surface of the aperture member 66 and lower surfaces of the metal contacts 61 exposed. Finally, as shown in FIG. 6E, the individual package is punched out or cut from any attached frame to become a finished package.

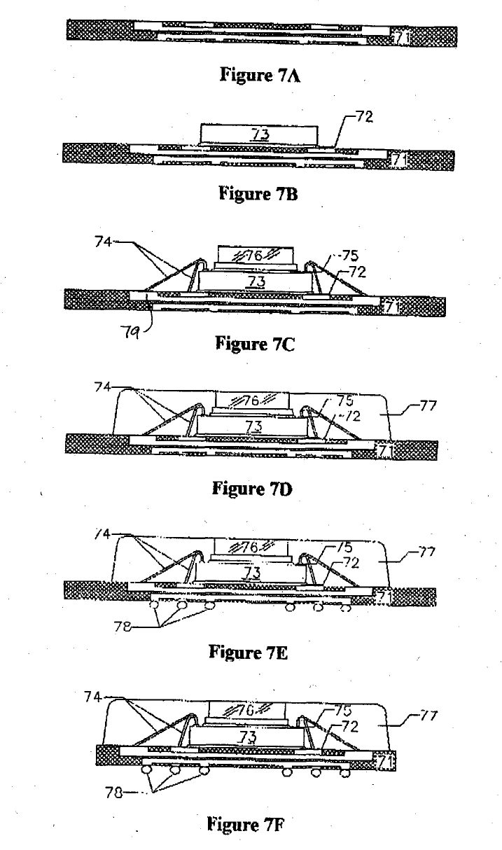

FIGS. 7A through 7E show the assembly of an embodiment especially suited for Ball Grid Array (BGA) or Land Grid Array (LGA) packages. As shown in FIG. 7A, a Printed Circuit Board (PCB) substrate 71 comprising rubber, bismallimide triazene (BT), a ceramic, or other suitable material as is known in the art is configured to accommodate a desired semiconductor and related electrical circuitry.

FIG. 7B shows a semiconductor die 73 attached by an adhesive material 72 to the upper surface of the substrate 71. The adhesive material 72 may be dispensed, stamped, laminated, or applied by other means known in the art atop the substrate 71. The adhesive material 72 can be a silver-filled epoxy, a polyimide epoxy, a thermally-conductive epoxy, a thermally or electrically nonconductive epoxy, an adhesive tape, or a metal alloy. The adhesive material 72 is heated and cured, thereby securing the semiconductor die 73 to the substrate 71.

In FIG. 7C, metal wires 74 are bonded between the PCB circuitry 79 and the semiconductor die circuitry (not shown). The metal wires 74 may comprise gold, aluminum, copper or other suitable materials as are known in the art. An aperture member 76 is attached upon an optically-sensitive area of the die with a transparent adhesive material 75. The transparent adhesive material 75 may be dispensed, stamped, laminated, or applied by other means known in the art to either upper surface of the semiconductor die 73 or the lower surface of the aperture member 76.

FIG. 7D shows a cross-sectional view of the present invention after the semiconductor die 73, the aperture member 76, and the upper portions of the substrate 71 are encapsulated with an epoxy molding compound as is known in the art, forming a package 77 while leaving the upper surface of the aperture member 76 and lower surfaces of the substrate 71 exposed.

Finally, FIG. 7E shows attachment of solder balls 78 to terminals on the lower side of the substrate 71 for a BGA package. The solder balls 78 are not required on an LGA package. Finally, the individual package is punched out or cut from any attached substrate to become a finished package.

The embodiments described above utilize pre-cut aperture members rather than wafer-sized sheets, eliminating extra cutting steps and allowing increased flexibility in selecting the size, position, and optical characteristics of each embedded window.

The principles, embodiments, and modes of operation of the present invention have been set forth in the foregoing specification. The embodiments disclosed herein should be interpreted as illustrating the present invention and not as restricting it. For example, it should be recognized that a lead frame might be replaced with a printed circuit board (PCB) or a wired circuit board (WCB), and that an optoelectronic sensor might be replaced by a light-emitting semiconductor. Additionally, the assembly steps may be varied from the orders described, and in each case prior to assembly the transparent adhesive may be applied first to the aperture member or to both the die and the aperture member. In any embodiment of the present invention a pick-and-place machine may select a different type of aperture member for each of any number of sequentially-assembled optoelectronic packages.

The foregoing disclosure is not intended to limit the range of equivalent structure available to a person of ordinary skill in the art in any way, but rather to expand the range of equivalent structures in ways not previously contemplated. Numerous variations and changes can be made to the foregoing illustrative embodiments without departing from the scope and spirit of the present invention.

1. A method comprising:
bonding an optical semiconductor element to a lead frame, the optical semiconductor element having a radiation-sensitive portion;
applying a transparent adhesive element to at least the radiation-sensitive portion; and
applying an aperture member to the transparent adhesive element.

2. A method comprising:
bonding an optical semiconductor element to a lead frame, the optical semiconductor element having a radiation-sensitive portion;
applying a transparent adhesive element to at least the radiation-sensitive portion;
selecting an aperture member; and
applying the aperture member to the transparent adhesive element.

3. A method as claimed in claim 2, wherein the aperture member is selected for a least one physical characteristic.

4. A method as claimed in claim 2, wherein the aperture member is selected and applied to the transparent adhesive element by a programmable pick-and-place semiconductor assembly machine.

5. A method as claimed in claim 2, wherein the optical semiconductor element is bonded to the lead frame with a bonding agent selected from the group consisting of a silver-filled epoxy, a polyimide epoxy, a thermally conductive epoxy, a thermally nonconductive epoxy, an electrically nonconductive epoxy, an adhesive tape, and a metal alloy.

6. A method as claimed in claim 2 wherein the transparent adhesive element is selected from the group consisting of silicon, polyimide epoxy, and adhesive tape.

7. A method as claimed in claim 2, comprising the additional step of bonding at least a first connecting electrical conductor between at least a first circuit contact on the optical semiconductor element and at least a first lead on the lead frame.

8. A method as claimed in claim 7, wherein the first connecting electrical conductor comprises a wire fabricated from a metal selected from the group consisting of gold, aluminum, and copper.

9. A method as claimed in claim 2, comprising the additional step of encapsulating the optical semiconductor element, the transparent adhesive element, and the aperture member with an encapsulating agent.

10. A method as claimed in claim 9, wherein the encapsulating agent is an epoxy molding compound.

11. A method comprising:
bonding an optical semiconductor element to a printed circuit board, the optical semiconductor element having a radiation-sensitive portion;
applying a transparent adhesive element to at least the radiation-sensitive portion;
selecting an aperture member; and
applying the aperture member to the transparent adhesive element.

12. A method as claimed in claim 11, wherein the aperture member is selected for a least one physical characteristic.

13. A method as claimed in claim 11, wherein the aperture member is selected and applied to the transparent adhesive element by a programmable pick-and-place semiconductor assembly machine.

14. A method as claimed in claim 11, wherein the optical semiconductor element is bonded to the printed circuit board with a bonding agent selected from the group consisting of a silver-filled epoxy, a polyimide epoxy, a thermally-conductive epoxy, a thermally nonconductive epoxy, an electrically nonconductive epoxy, an adhesive tape, and a metal alloy.

15. A method as claimed in claim 11, wherein the transparent adhesive element is selected from the group consisting of silicon, polyimide epoxy, and adhesive tape.

16. A method as claimed in claim 11, comprising the additional step of bonding at least a first connecting electrical conductor between at least a first circuit contact on the optical semiconductor element and at least a first printed circuit board contact on the printed circuit board.

17. A method as claimed in claim 16, wherein the first connecting electrical conductor comprises a wire fabricated from a metal selected from the group consisting of gold, aluminum, and copper.

18. A method as claimed in claim 11, comprising the additional step of encapsulating the optical semiconductor element, the transparent adhesive element, and the aperture member with an encapsulating agent.

19. A method as claimed in claim 18, wherein the encapsulating agent is an epoxy molding compound.

20. A method comprising:
bonding an optical semiconductor element to a substrate, the optical semiconductor element having a radiation-sensitive portion;
applying a transparent adhesive element to at least the radiation-sensitive portion;
selecting an aperture member; and
applying the aperture member to the transparent adhesive element.

21. A method as claimed in claim 20, wherein the aperture member is selected for a least one physical characteristic.

22. A method as claimed in claim 20, wherein the aperture member is selected and applied to the transparent adhesive element by a programmable pick-and-place semiconductor assembly machine.

23. A method as claimed in claim 20, wherein the substrate comprises a material selected from the group consisting of rubber, ceramic, and bismallimide triazene.

24. A method as claimed in claim 20, wherein the substrate provides a least a first substrate electrical conductor.

25. A method as claimed in claim 20, wherein the optical semiconductor element is bonded to the substrate with a bonding agent selected from the group consisting of a silver-filled epoxy, a polyimide epoxy, a thermally-conductive epoxy, a thermally nonconductive epoxy, an electrically nonconductive epoxy, an adhesive tape, and a metal alloy.

26. A method as claimed in claim 20, wherein the transparent adhesive element is selected from the group consisting of silicon, polyimide epoxy, and adhesive tape.

27. A method as claimed in claim 24, comprising the additional step of bonding at least a first connecting electrical conductor between at least a first circuit contact on the optical semiconductor element and at least the first substrate electrical conductor.

28. A method as claimed in claim 27, wherein the first connecting electrical conductor comprises a wire fabricated from a metal selected from the group consisting of gold, aluminum, and copper.

29. A method as claimed in claim 20, comprising the additional step of encapsulating the optical semiconductor element, the transparent adhesive element, and the aperture member with an encapsulating agent.

30. A method as claimed in claim 29, wherein the encapsulating agent is an epoxy molding compound.

31. A method as claimed in claim 24, comprising the additional step of attaching at least a first solder ball to at least the first substrate electrical conductor.
